(19) United States
(12) Patent Application Publication
(10) Pub. No.: US 2026/0204989 A1
(43) Pub. Date: Jul. 16, 2026

(54) INVERTER HOUSING COMPRISING COOLING PADS AND INVERTER COMPRISING SUCH A HOUSING

(71) Applicant: NIDEC PSA EMOTORS, Carrieres Sous Poissy (FR)

(72) Inventors: Paul DOUBLET, SARTROUVILLE (FR); Gael BLONDEL, SEINE PORT (FR); Valery GOVINDASSAMY, EAUBONNE (FR)

(21) Appl. No.: 19/135,655

(22) PCT Filed: Nov. 15, 2023
(86) PCT No.: PCT/FR2023/051807

§ 371 Date: Jun. 4, 2025

(30) Foreign Application Priority Data
Dec. 7, 2022 (FR) 2212878

(51) Int. Cl. H02K 11/33; B60L 15/00; H10D 80/20; H10W 40/22; H10W 76/01; H10W 76/134

(52) U.S. Cl. CPC H02K 11/33; B60L 15/007; H10D 80/20; H10W 40/226; H10W 76/01; H10W 76/134

(57) ABSTRACT

The invention relates to an inverter housing for receiving at least one power electronics component (42, 43) of an inverter (4), wherein the housing (41) has walls (411) defining a receiving volume (V) for the at least one power electronics component (42, 43). The housing has at least one pad (47) protruding from an inner surface (412) of the walls (411) into the receiving volume (V), the at least one pad (47) being configured such that, when the at least one component is received in the receiving volume (V), a terminal (421, 422, 432) of this at least one power electronics component (42, 43) or a conducting bar electrically connected to the terminal (421, 422, 432) of the power electronics component (42) faces a free end (472) of the pad (47) at a predetermined distance such that an interface element (48) can be interposed between the free end (472) of the pad (47) and the terminal (421, 422, 432) of the power electronics component (42, 43) or the conducting bar.

### CROSS-REFERENCE TO RELATED APPLICATIONS

This application is the US National Stage under 35 USC § 371 of International Application No. PCT/FR 2023/051807, filed Nov. 15, 2023, which claims the priority of French application 2212878 filed on Dec. 7, 2022, the content (text, drawings and claims) of both said applications being incorporated by reference herein.

### BACKGROUND

The methods and devices described herein relate to the field of cooling electrical inverters. They especially relate to inverters that are suitable for controlling the operation of an electric traction machine of an electric or hybrid vehicle, for example a motor vehicle.

In the field of power electronics, an inverter is a voltage converter used to generate alternating voltages and currents from an electrical energy source of a different voltage or frequency. In particular, an inverter can be used to generate the AC voltages required to operate an electric motor, whether synchronous or asynchronous, from a DC voltage source, such as an electric battery.

For this purpose, inverters comprise components, in particular power modules including electronic switches, such as IGBTs (which stands for Insulated Gate Bipolar Transistor), whose openings and closings are appropriately controlled.

An inverter of this type thus comprises an assembly of several components which are generally enclosed in a protective casing, also known as a housing. These components typically have one or more terminals enabling them to be interconnected, or connected to other inverter-related components such as the electric battery or an electric machine.

During operation, the inverter's components generate heat which can impair their proper functioning or damage them. In particular, power modules generate heat due to the current flowing through them and the frequent switching of electronic switches.

The heat generated by the power modules can be transmitted, via the terminals, to other inverter components, such as capacitors which may be sensitive to heat, and/or to inverter-related components. Heat is also generated in the terminals due to the current flowing through them.

In addition, inverter components other than power modules, as well as inverter-related components, can also generate heat; this heat can be transferred to the power modules via the terminals, further heating these power modules.

A number of general solutions have been developed to reduce the heat generated by conducting bars, also known as bus bars.

For example, US20200044422 proposes an inverter housing comprising a recess wherein a thermally conductive liquid is received. The housing comprises a bus bar device with bus bars, one end of which is immersed in the conductive liquid.

However, this solution is imperfect in that it involves a specific arrangement of the device, wherein the conducting bars are offset to be brought into the recess. This solution therefore requires the manufacture of complex and specific parts, and entails high production costs. These production costs are all the higher because conducting bars are generally made of copper.

The aim is to thermally protect the components of an inverter, while solving some or all of the problems indicated above. In particular, the aim is to limit the heat exchanged between two components and transmitted via the terminals of these components.

### SUMMARY

To this end, a first aspect proposes an inverter housing designed to receive at least one power electronics component of an inverter, the housing comprising walls defining a reception volume for the at least one power electronics component.

The inverter housing comprises at least one pad protruding from an inner surface of the walls into the receiving volume, the at least one pad being thermally conductive and adapted to drain heat to a cooling system of the inverter, the at least one pad being configured such that, when the at least one component is received in the receiving volume, a terminal of this at least one power electronics component or a conducting bar electrically connected to the terminal of the power electronics component faces a free end of the pad at a predetermined distance so that a thermally conductive interface element can be interposed between the free end of the pad and the terminal of the power electronics component or the conducting bar.

The term “power electronics component” refers, in the context of an inverter, to any component of this inverter through which an electric current flows. For example, such a power electronics component may be a power module, a capacitor, an electronic board or a filter, such as an EMC filter.

The term “terminal” refers to a device, usually metal, which allows current to flow into or out of an electronic component.

The term “thermally conductive” refers to an element with a thermal conductivity greater than or equal to 1 W/mK.

In the inverter housing, the pad is arranged at a location which, when a power electronics component is received in the receiving volume, faces a terminal of this component in the vicinity. The pad may also face a conducting bar, which is electrically connected to the terminal of the power electronics component. In particular, such a conducting bar is used to conduct an electric current and electrically interconnect a plurality of inverter components, or an inverter component with a component external to the inverter.

When the component is received in the receiving volume, the pad fills part of the gap between the terminal or conducting bar and the internal surface at the location of the pad. The remaining part of this gap, that is, the distance between the free end of the pad and the terminal or conducting bar, is designed to be filled by a thermally conductive interface element.

The interface element ensures thermal conduction between the terminal or conducting bar and the pad. In this way, the pad brings a thermally conductive surface close to a terminal of a power electronics component or a conducting bar, in order to drain the heat generated by this terminal towards the walls of the housing. Thanks to the pad, at least some of the heat from the terminal or conducting bar is drained off to the housing's cooling system.

This limits heat exchange, transmitted via such terminals, between two components connected to each other via these terminals. Thanks to the pad, the housing can be adapted to different components with different terminal shapes, for example. In fact, such a housing eliminates the need for any structural modification of the components, particularly the terminals.

When the pad is electrically conductive, which may be the case depending on the material from which it is made, the interface element ensures, in addition to thermal conduction, electrical insulation between the pad and the terminal.

The described devices may optionally comprise one or more of the following features in combination or not.

The at least one pad can be made of aluminum or aluminum alloy.

Aluminum offers a number of advantages, including high thermal conductivity around 226 W/mK (watts per meter-kelvin) compared with 0.025 W/mK for air-and relatively low density. In fact, an aluminum pad provides improved heat transfer while limiting the mass of the inverter housing.

The at least one pad can be integral with the inverter housing. As the housings are generally molded, preferably by die-casting, only the mold needs to be adapted for the manufacture of such a housing. In particular, such molding enables the manufacture of aluminum or aluminum alloy housings. Such an arrangement also provides improved heat transfer compared with a pad attached to the housing, as there is no interface between the two elements.

The pad can be made of the same material as the housing, the housing preferably being made of aluminum or an aluminum alloy.

The at least one pad can have a substantially constant cross-section of less than 300 mm2, preferably less than 260 mm2. In die-cast parts, one of the most common causes of porosity is uneven cooling of the part inside the mold. This is because the material in contact with the mold walls cools down faster than the material furthest from the walls. It was found that by limiting the cross-section of the pads to 300 mm2, the porosity rate was reduced compared to pads with a larger cross-section. This also reduces the risk of gas or liquid leaks.

The cross-section of at least one pad can be square, rectangular, circular, oblong, T-shaped, L-shaped, cross-shaped or a combination of these shapes.

The at least one pad can be at least partially covered with an electrically insulating outer layer, the interface element comprising said electrically insulating outer layer. Such a layer can be obtained following a surface treatment, such as anodizing or coating with an electrically insulating material. It is easier to carry out this treatment on at least one pad, or even on the whole housing, rather than on one terminal of the component, given that the housing generally accommodates several components each with several terminals. Such a layer contributes to the electrical insulation between the pad and the terminal, without considerably increasing the manufacturing and/or preparation time of the inverter housing.

The cooling system may comprise a chamber provided in the inverter housing and adapted to the circulation of a cooling fluid, the chamber being arranged below a receiving area of the at least one power electronics component to be cooled. Such a cooling system can transfer some of the heat generated by the component away from the inverter. The at least one pad transfers another part of the heat generated by the component and transmitted through the terminal to this cooling system. As a result, more heat is transferred to the cooling system for more efficient overall heat dissipation.

Advantageously, the inverter housing can comprise two pads arranged on either side of the receiving area so that the free ends of these pads are intended to face each other at a predetermined distance from terminals of the power electronics component, said terminals being located on opposite sides of the power electronics component.

According to a second aspect, also related herein is an inverter comprising an inverter housing as described above, at least one power electronics component housed in the receiving volume and a thermally conductive interface element interposed and held in contact between a free end of the at least one pad and a terminal of the at least one power electronics component or a conducting bar electrically connected to the terminal of the power electronics component, the interface element ensuring thermal conduction between the terminal of the power electronics component or the conducting bar and the pad.

Such an inverter offers similar advantages to those described above in relation to the inverter housing.

The interface element may comprise a flexible solid body. The term “flexible solid body” refers to an element that is relatively firm and non-liquid, yet relatively flexible, in particular deformable under the weight of a power electronics component.

This body compensates for assembly clearances and surface irregularities by deforming slightly. Thanks to its deformability, the body also keeps the terminal and pad in contact despite deformations due to thermal expansion of the terminal and/or pad materials. In other words, the body allows such deformations to be absorbed while guaranteeing that contact is maintained between the pin and the terminal. The flexible solid body can be a hardened thermal paste, preferably made from silicone. The thermal paste, also known as gap filler, is generally softer than the outer layer. As a result, the thermal paste can deform further under the weight of the component, and have a greater contact surface, enabling satisfactory heat transfer between the terminal and the interface element. Over time, the thermal layer cures, but remains relatively flexible.

Alternatively, the flexible solid body can be a thermal foam. Such foam has the ability to be deformed and return to its original shape. What's more, this foam provides at least partial vibration damping.

Alternatively, the flexible solid body can be a silicone-coated plate, also known as a gap pad.

Alternatively, the flexible solid body can be an adhesive.

The interface element can comprise both the electrically insulating outer layer and a flexible solid body from the alternatives described above. Such an arrangement is particularly useful when the pad is electrically conductive and the flexible solid body is not perfectly electrically insulating. This also reduces the height, or thickness, of the solid flexible body.

The ratio between a height of the pad to a height of the interface element along an axis of extension of the pad can be greater than one, preferably substantially equal to two. In other words, the height of the pad is preferably twice the height of the interface element, along the axis of extension of the pad. It has been found that the rigidity and mechanical strength of the assembly formed by the pad, the interface element and the component are improved when the height of the pad is greater than the height of the interface element (when the ratio is greater than one). It has also been found that, in addition to improving the rigidity and mechanical strength of this assembly, component assembly and inverter manufacture are facilitated when the height of the pad is substantially twice the height of the interface element.

The height of the interface element along an axis of extension of the pad can be between 0.5 mm and 6 mm, preferably between 3 mm and 5 mm.

The component can have at least one input terminal, that is, through which current enters the component, with at least one separate pad associated with each input terminal. The component can have at least one output terminal, that is, through which current flows out of the component, with at least one separate pad associated with each output terminal. As previously described, one of the most common causes of porosity is uneven cooling of the part inside the mold. This avoids the need for massive blocks in the housing, either when one component has several terminals, or when the housing has several components each with at least one terminal.

Preferably, the inverter can comprise three components, each with three input terminals and one output terminal. Such an arrangement is generally used for a three-phase inverter. In this case, the components are power modules. In particular, in this arrangement the inverter housing has at least nine separate pads associated with the input terminals and at least three separate pads associated with the output terminals.

Two separate pads can be associated with one of the input terminals of each component, and a separate pad can be associated with each of the other input terminals and the output terminal. In this arrangement, the inverter housing has twelve separate pads associated with the input terminals and at least three separate pads associated with the output terminals. As described above, this arrangement further reduces the porosity of the inverter housing.

A third aspect is a method for manufacturing an inverter. The method comprises:

a step for supplying an inverter housing as described above,

a step of depositing the interface element on the free end of the at least one pad, and

a step for positioning a terminal of the power electronics component or conducting bar on the interface element.

Such a method offers similar advantages to those described above in relation to the inverter housing and the inverter.

The interface element may comprise a flexible solid body. The deposition step may then involve depositing at least two superimposed layers of the interface element's flexible solid body. The flexible body can be deposited in paste form.

In order to achieve the desired height of the interface element, laying down two thin layers each having a height less than the desired height, rather than one layer having the desired height directly, prevents the body from spreading. This improves the mechanical strength of the body and therefore of the interface element.

The positioning step can be followed by a curing step for the flexible body, particularly when the flexible body is deposited in paste form.

### BRIEF DESCRIPTION OF THE FIGURES

The described devices and methods, according to one embodiment, will be well understood and its advantages will become clearer on reading the following detailed description, given by way of indication and in no way limiting, with reference to the appended drawings.

FIG. 1 shows a schematic view of an electric or hybrid motor vehicle comprising an electrical machine, a battery and an inverter in accordance with one embodiment.

FIG. 2 is a cross-sectional view of the inverter shown in FIG. 1, the inverter comprising a housing according to a first embodiment.

FIG. 3 is a partial top view of a housing in a second embodiment, showing a receiving area for a first power electronics component.

FIG. 4 is a partial perspective view of the housing shown in FIG. 3, showing a receiving area for a second power electronics component. FIG. 5 is a diagram showing a manufacturing method for an inverter.

### DETAILED DESCRIPTION

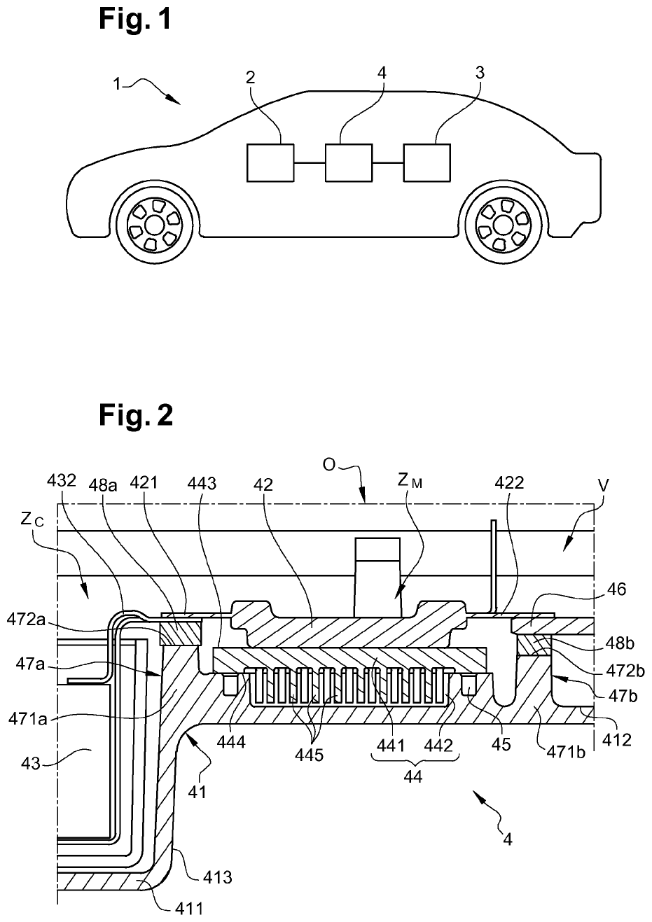

FIG. 1 shows a schematic diagram of a vehicle 1, for example a hybrid or electric vehicle. The vehicle 1 comprises an electrical machine 2, a battery 3 and an inverter 4 electrically connected to electrical machine 2 and battery 3.

The electric machine 2 is configured to propel the vehicle 1.

The inverter 4 is configured to generate an AC voltage suitable for operating the electrical machine 2 from a DC voltage supplied by the battery 3.

The inverter 4, conforming to a first embodiment, is best seen in FIG. 2.

The inverter 4 comprises a housing 41, or casing, configured to house inverter components. The housing 41 has walls 411 with an inner surface 412 and an outer surface 413 opposite the inner surface 412.

The walls 411 define, on the side of the internal surface 412, a volume V for receiving the components of the inverter 4. The walls 411 also define an opening O for access to the receiving volume V, e.g. for component assembly.

The housing 41 is adapted to be mechanically connected to a housing of electrical machine 2. The opening O is intended to face the electrical machine 2 when the housing 41 of the inverter 4 is mechanically connected to the housing of the electrical machine 2, so that inverter components and electrical machine components can be interconnected.

The opening O is bordered, for example, by a sealing element (not shown) which is intended to seal the receiving volume V when the housing 41 is mechanically connected to the housing (not shown) of the electrical machine 2.

The housing 41 is made of aluminum or aluminum alloy, for example.

In the example shown in FIG. 2, the walls 411 of the housing 41 define, within the receiving volume V, a first receiving area Z_{M} for an inverter component 4. The walls 411 of the housing 41 also define, in the vicinity of the first receiving area Z_{M}, a second receiving area Z_{C} for another component of the inverter 4.

The inverter 4 comprises a cooling system 44. The cooling system 44 is configured to cool a component of the inverter 4 located in the first receiving area Z_{M}. The cooling system 44 is also configured to cool the walls 411 of the housing 41.

The cooling system 44 comprises a thermally conductive plate 441, attached to the inner surface 412 of the walls 411 and defining, with this inner surface, a sealed chamber 442.

To this end, the housing 41 has a seal 45 positioned between the plate 441 and the inner surface 412.

The sealed chamber 442 is suitable for the circulation of a cooling fluid, for example a coolant such as water. For example, the chamber 442 is connected to a cooling circuit (not shown) featuring a heat exchanger, through which the cooling fluid circulates.

The plate 441 is configured to drain heat to the chamber 442. In particular, the plate 441 has a substantially flat first face 443 and a second face 444, opposite the first face, provided, on at least part of this face, with a number of thermally conductive fins 445. The first face 443 of the plate 441 faces the opening O of the housing 41 and the second face 444 faces the inner surface 412 of the walls 411, so that the fins 445 extend into the sealed chamber 442. These fins 445 are arranged so as to be in contact with the cooling fluid in order to transfer the drained heat to the cooling fluid.

The housing 41 has pads 47 protruding from the inner surface 412 of the housing 41 into the receiving volume V. The pads 47 are thermally conductive and adapted to drain heat to the cooling system 44 of the inverter 4. In particular, each pad 47 is configured to drain heat generated at a terminal of an inverter component.

In FIG. 2, the pads 47 are arranged on either side of the first receiving area Z_{M}. In particular, FIG. 2 shows a first pad 47a, located to the left of the first receiving area Z_{M} in FIG. 2, and a second pad 47b, located to the right of the receiving area Z_{M} in FIG. 2.

Each of these pads 47a, 47b has a connection end 471a, 471b attached to the walls 411 and a free end 472a, 472b which is distal from the connection end 471a, 471b. The free ends 472a, 472b of the pads 47 are relatively flat and belong to the same plane.

Each pad 47 has a height, along an axis of extension of the pad, of between 1 mm and 12 mm. This height corresponds to the distance between the connection end 471 and the free end 472. The extension axis of the pad is perpendicular to the internal surface 412.

In particular, the height of the first pad 47a corresponds to the distance between the internal surface 412 located directly to the right of this first pad 47a in FIG. 2 and its free end 472a, while the height of the second pad 47b corresponds to the distance between the internal surface 412 located on either side of this second pad 47b in FIG. 2 and its free end 472b.

The pads 47 have a substantially constant cross-section over their entire height. This cross-section has, for example, a surface area of between 4 mm2 and 300 mm2, preferably between 10 mm² and 260 mm², and even more preferably between 16 mm² and 256 mm². The cross-section is generally square, for example.

For example, the pads 47 are made of aluminum or an aluminum alloy.

Here, the pads 47 are integral with the housing 41.

The inverter 4 further comprises a first power electronics component 42, a second power electronics component 43 and an electrical connector 46.

The first power electronics component 42 is, for example, a power module comprising power switches whose openings and closings are suitably controlled to generate, from a DC voltage, an AC voltage of predetermined frequency.

The first power electronics component 42 is received in the first receiving area Z_{M} of the housing 41.

The first power electronics component 42 comprises an input terminal 421 and an output terminal 422. For example, the input terminal 421 is intended to be electrically connected to a component supplying a DC voltage, such as the second power electronics component 43, while the output terminal 422 is intended to be electrically connected to a component receiving an AC voltage, such as electrical machine 2.

The electrical connector 46 is, for example, a conducting bar for electrically connecting the first power electronics component 42 to the electrical machine 2.

The second power electronics component 43 is formed, for example, by a set of capacitors configured to smooth the DC voltage supplied by the battery 3.

The second power electronics component 43 is received in the second receiving area Zc of the housing 41.

The second power electronics component 43 has an input terminal (not shown) and an output terminal 432. For example, the input terminal is intended to be electrically connected to a component supplying a DC voltage, such as the battery 3 or an inverter filter, and the output terminal 432 is intended to be electrically connected to a component receiving a DC voltage, such as the first power electronics component 42.

The inverter 4 comprises an interface element 48 configured to form a thermally conductive and, for example, electrically insulating interface between the terminals of the components of the inverter 4, in particular the first power electronics component 42 and the second power electronics component 43, and the free end 472 of the pads 47.

The interface element 48 comprises a body that is both solid and flexible. This body is a thermal paste, preferably made from silicone. For example, the thermal paste has a thermal conductivity of between 1 W/mK and 10 W/mK, for example substantially equal to 4 W/mK. The thermal paste is able to cure, but remains relatively flexible, particularly under the effect of the weight of the components.

In the present embodiment of the inverter 4, the first power electronics component 42 is positioned on the first side 443 of the cooling system plate 441. In this way, some of the heat generated by the first power electronics component 42 is transferred to the cooling system 44.

The input terminal 421 of the first power electronics component 42 faces the free end 472a of the first pad 47a. The output terminal 422 of the first power electronics component 42 faces the free end 472b of the second pad 47b.

The output terminal 432 of the second power electronics component 43 faces the free end 472a of the first pad 47a.

The input terminal 421 of the first power electronics component 42 and the output terminal of the second power electronics component 43 are superimposed and attached to each other, for example by laser welding, to establish their electrical connection.

The electrical connector 46 faces the free end 472b of the second pad 47b.

The output terminal 422 of the first power electronics component 42 and the electrical connector 46 are superimposed and in contact with each other to establish their electrical connection. The output terminal 422 and the electrical connector 46 are attached to each other, for example by laser welding.

In FIG. 2, the interface element 48 is arranged at the first pad 47a and at the second pad 47b. In particular, FIG. 2 shows a first interface element 48a, located on the first pad 47a, and a second interface element 48b, located on the second pad 47b.

The first interface element 48a is interposed and held in contact between the free end 472a of the first pad 47a and one of the output terminal 432 and the input terminal 421, depending on whether the output terminal 432 is located above or below the input terminal 421.

The second interface element 48b is interposed and held in contact between the free end 472b of the second pad 47b and one of the output terminal 422 and the electrical connector 46, depending on whether the output terminal 422 is located above or below the electrical connector 46.

The body of the interface element 48, for example, is arranged on the free end 472 of each pad 47.

The interface element 48 is slightly compressed between the free end 472 of each pad 47 and the associated terminals. Each interface element 48 has a height, once compressed and along an axis of extension of the pad 47 on which this interface element 48 is arranged, of between 0.5 mm and 6 mm. Preferably, the height of the interface element 48 is between 3 mm and 5 mm.

The ratio between the height of each pad 47 and the height of the interface element 48 arranged on this pad 47 is greater than one, preferably substantially equal to two.

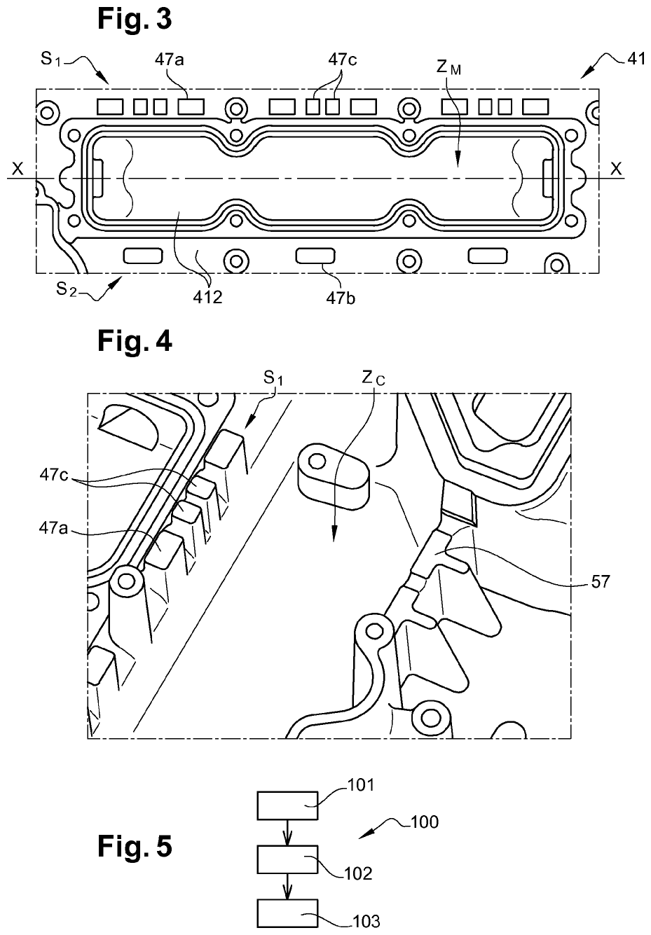

FIG. 3 shows an inverter housing according to a second embodiment. In this figure, the cooling system plate and gasket are not shown.

The housing 41 according to the second embodiment is suitable, for example, for a three-phase inverter.

The housing 41 according to the second embodiment is designed to accommodate three first power electronics components 42, each with three input terminals 421 and one output terminal 422.

The walls 411 of housing 41 define a first receiving area Z_{M} configured to receive three first power electronics components 42. The first receiving area Z_{M} is generally elongated and extends along an alignment direction X-X. The first power electronics components 42 are intended to be aligned along the alignment direction X-X so that the input terminals 421 and output terminals 422 are aligned with each other.

In this embodiment, the pads 47 are arranged in a first series S₁ on one side of the receiving area Z_{M} and a second series S₂ on the other side of the first receiving area.

The first series S₁ and the second series S₂ are parallel to the X-X alignment direction.

The pads 47a, 47c of the first series S₁are configured so that, when the first power electronics components 42 are received in the first receiving area Z_{M}, each input terminal 421 faces at least one pad 47a or 47c of this first series S₁.

In particular, the first series S₁ comprises pads 47a, 47c of different cross-sections, namely single pads 47a and double pads 47c. Each double pad 47c is formed by two separate pads, each with a cross-section, for example square, whose area is smaller than the area of a cross-section of a single pad 47a, which has a substantially rectangular cross-section.

The first series S₁ features alternating single pads 47a and double pads 47c along the X-X alignment direction. In particular, the first series S₁ comprises nine separate pads 47a, 47c, including six single pads 47a and three double pads 47c.

The pads 47b of the second series S₂ are configured so that, when the first power electronics components 42 are received in the first receiving area Z_{M}, each output terminal 422 faces one pad 47b of this second series S₂.

In particular, the second series S₂ comprises three separate 47b pads. These pads 47b are substantially oblong in cross-section, with their longest axis parallel to the X-X alignment direction.

FIG. 4 shows the second zone Z_{C} for receiving the inverter housing according to the second embodiment. Part of the first series S₁ of pads 47a, 47c is visible on the left of this figure. The first series S₁ is arranged along a first side of the second receiving area Z_{C}. The inverter housing 41 has pads 57 on one side of the second receiving area Z_{C}, opposite the side on which the first series S₁ of pads 47 is located.

Each pad 57, for example, is configured to face a predetermined distance from an input terminal (not shown) of the second power electronics component.

Unlike the pads 47 of the first series S₁ or the second series S₂ described with reference to FIG. 3, the pads 57 have a T-shaped cross-section. Like the pads 47, the pads 57 have a substantially constant cross-section of less than 300 mm2, preferably less than 260 mm2 .

FIG. 5 shows method 100 for manufacturing the inverter 4. The manufacturing method 100 includes a step 101 of supplying a housing according to the first embodiment or according to the second embodiment. For example, the housing is cast, preferably die-cast, from aluminum or an aluminum alloy.

The manufacturing method 100 then includes a step of depositing 102 the interface element on the free end of the pads. The deposition step 102 involves, for example, the deposition of two superimposed layers of the body of the interface element, that is, the thermal paste.

Finally, the manufacturing method 100 includes a step 103 of positioning the terminals of a first power electronics component and/or the terminals of a second power electronics component on the interface element. Preferably, the first power electronics component and/or the second power electronics component are only deposited on the interface element, that is, they press on the interface element only under the effect of their weight.

Of course, various modifications can be made by the a person skilled in the art without going beyond the scope.

The housing can be produced using a different manufacturing method. Alternatively, the housing is produced by additive manufacturing, more commonly known as 3D printing.

The structure of the housing may vary. Alternatively, the housing can have more or fewer pads. Alternatively, each pad has a different cross-sectional shape or height.

According to a variant not shown, the pads are attached to the housing, for example by gluing, welding, screwing, press-fitting or any other known method of securing two components together. In this case, the pads can be made from a different material than that of the housing. For example, the pads can be made of a metal other than aluminum, such as copper.

The structure of the cooling system may vary. Alternatively, the cooling system is external to the housing. Alternatively, the cooling system is formed by the outer surface of the housing in contact with the ambient air.

The interface element may vary. Alternatively, the interface element can comprise an electrically insulating outer layer. The layer is obtained, for example, by a surface treatment such as anodizing. In this case, the body of the interface element is a layer of alumina. Alternatively, the layer is obtained by spraying or coating with an electrically insulating material.

According to these variants, the deposition step comprises a sub-step of surface treatment, spraying or coating.

Alternatively, the interface element comprises two superimposed bodies, namely a first body and a second body. In this case, the first body is, for example, an electrically insulating outer layer as described above, and the second body is a thermal paste as previously described. In this case, the second body is interposed between the first body and the terminals.

According to this variant, the deposition step comprises a sub-step of surface treatment, sputtering or coating, followed by the deposition of two layers of the second body.

Inverter structure may vary. Alternatively, the inverter comprises a single power electronics component. Alternatively, the inverter comprises more than two power electronics components.

According to a variant not shown, one of the first power electronics component and the second power electronics component is a power module, a capacitor, an electronic board or a filter, for example an EMC filter. Component structure may vary. Alternatively, the power electronics components have only one input terminal or one output terminal. Alternatively, the components have more than one input terminal and/or more than one output terminal.

In a variant not shown, the first power electronics component and the second power electronics component are mounted on an electronic board.

The described methods and devices thus make it possible to drain some of the heat generated by the components of an inverter, while facilitating the assembly of these components. The inverter housing is simple to manufacture. In fact, its manufacture requires very few modifications compared with previous housings. In addition, the manufacture of the inverter can be automated.

Although in the above description, particular aspects, notably the implementation of the inverter, have been described in the context of a motor vehicle, the inverter could be implemented in other configurations, notably with other types of vehicle.

1. An inverter housing for receiving at least one power electronics component of an inverter, the housing comprising walls defining a receiving volume for the at least one power electronics component, wherein it comprises at least one pad protruding from an inner surface of the walls into the receiving volume, the at least one pad being thermally conductive and adapted to drain heat to a cooling system of the inverter, the at least one pad being configured so that, when the at least one component is received in the receiving volume, a terminal of this at least one power electronics component or a conducting bar electrically connected to the terminal of the power electronics component faces a free end of the pad at a predetermined distance so that a thermally conductive interface element can be interposed between the free end of the pad and the terminal of the power electronics component or the conducting bar.

2. The inverter housing according to claim 1, wherein the at least one pad is integral with the inverter housing.

3. The inverter housing according to claim 1, wherein the pad is made of the same material as the housing, the housing preferably being made of aluminum or an aluminum alloy.

4. The inverter housing according to claim 1, wherein the at least one pad is at least partially covered with an electrically insulating outer layer, the interface element comprising said electrically insulating outer layer.

5. The inverter housing according to claim 1, wherein the at least one pad has a substantially constant cross-section of less than 300 mm2 , preferably less than 260 mm2 .

6. The inverter housing according to claim 1, wherein the cooling system comprises a chamber provided in the inverter housing and adapted to the circulation of a cooling fluid, the chamber being arranged below a receiving area of the at least one power electronics component to be cooled.

7. The inverter housing according to claim 6, wherein it comprises two pads arranged on either side of the receiving area of the power electronics component so that the free ends of these pads are intended to face each other at a predetermined distance from terminals of the power electronics component, said terminals being located on opposite sides of the power electronics component.

8. The inverter comprising an inverter housing according to claim 1, at least one power electronics component housed in the receiving volume and a thermally conductive interface element interposed and held in contact between a free end of the at least one pad and a terminal of the at least one power electronics component or a conducting bar electrically connected to the terminal of the at least one component, the interface element ensuring thermal conduction between the terminal of the power electronics component or the conducting bar and the pad.

9. The inverter according to claim 8, wherein the interface element comprises a flexible solid body.

10. The inverter according to claim 9, wherein the flexible solid body is a hardened thermal paste, preferably made from silicone.

11. The inverter according to claim 8, wherein the ratio between a height of the pad to a height of the interface element along an axis of extension of the pad is greater than one, preferably substantially equal to two.

12. The inverter according to claim 8, wherein the interface element has a height, along an axis of extension of the pad of between 0.5 mm and 6 mm, preferably between 3 mm and 5 mm.

13. A method for manufacturing an inverter, comprising:
a step of supplying an inverter housing according to claim 1,
a step of depositing the interface element on the free end of the at least one pad, and
a step of positioning a terminal of the power electronics component or conducting bar on the interface element.

14. The manufacturing method according to claim 13 wherein the interface element comprises a flexible solid body, characterized in that wherein the deposition step comprises the deposition of at least two superimposed layers of the flexible solid body of the interface element.
